(19) United States
(12) Patent Application Publication
(10) Pub. No.: US 2026/0186425 A1
(43) Pub. Date: Jul. 2, 2026

(54) SUBSTRATE HOLDER, LITHOGRAPHIC APPARATUS, COMPUTER PROGRAM AND METHOD

(71) Applicant: ASML NETHERLANDS B.V., Veldhoven (NL)

(72) Inventors: Rick Jeroen MEIJERINK, Den Bosch (NL); Marco Adrianus VAN DEN HEUVEL, Waalre (NL); Martijn VAN DER MAADEN, Waalre (NL); Si-Han ZENG, Eindhoven (NL); Juan Camilo PÉREZ MUÑOZ, Eindhoven (NL)

(73) Assignee: ASML NETHERLANDS B.V., Veldhoven (NL)

(21) Appl. No.: 18/865,364

(22) PCT Filed: May 31, 2023
(86) PCT No.: PCT/EP2023/064583

§ 371 Date: Nov. 13, 2024

(30) Foreign Application Priority Data
Jul. 11, 2022 (EP) 22184122.4
Jan. 12, 2023 (EP) 23151317.7

(51) Int. Cl. G03F 7/00; G03F 9/00; H10P 72/78

(52) U.S. Cl. CPC G03F 7/707; G03F 7/70775; G03F 7/70841; G03F 7/70991; G03F 9/7003; H10P 72/78

(57) ABSTRACT

A substrate holding system for supporting a substrate, the substrate holding system including a substrate holder and an evacuation conduit, wherein the substrate holder includes: a main body having a surface; a plurality of burls projecting from the surface and having distal ends that form a support surface for a substrate; and an evacuation passage in fluid communication with the evacuation conduit and a space between the surface and a substrate supported by the burls to form an evacuation flow path; and a proportional valve in the evacuation flow path.

### CROSS-REFERENCE TO RELATED APPLICATIONS

This application claims priority of EP application 22184122.4 which was filed on Jul. 11, 2022 and EP application 23151317.7 which was filed on Jan. 12, 2023 which are incorporated herein in its entirety by reference.

### FIELD

The present invention relates to a substrate holder for supporting a substrate, a lithographic apparatus comprising the substrate holder, a method of supporting a substrate on the substrate holder, and a method of clamping a substrate on the substrate holder.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as “Moore's law”. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm.

A lithographic apparatus may include an illumination system for providing a projection beam of radiation, and a support structure for supporting a patterning device. The patterning device may serve to impart the projection beam with a pattern in its cross-section. The apparatus may also include a projection system for projecting the patterned beam onto a target portion of a substrate.

In a lithographic apparatus the substrate to be exposed (which may be referred to as a production substrate) may be held on a substrate holder (sometimes referred to as a wafer table). The substrate holder may be moveable with respect to the projection system. The substrate holder usually comprises a solid body made of a rigid material and having similar dimensions in plan to the production substrate to be supported. The substrate-facing surface of the solid body may be provided with a plurality of projections (referred to as burls). The distal surfaces of the burls may conform to a flat plane and support the substrate. The burls can provide several advantages: a contaminant particle on the substrate holder or on the substrate is likely to fall between burls and therefore does not cause a deformation of the substrate; it is easier to machine the burls so their ends conform to a plane than to make the surface of the solid body flat; and the properties of the burls can be adjusted, e.g. to control clamping of the substrate to the substrate holder.

Production substrates may become distorted during the process of manufacturing devices, especially when structures with significant height, e.g. so-called 3D-NAND, are formed. Often substrates may become “bowl-shaped”, i.e. are concave viewed from above, or “umbrella-shaped”, i.e. convex viewed from above. For the purpose of the present disclosure the surface on which device structures are formed is referred to as the top surface. In this context, “height” is measured in the direction perpendicular to the nominal surface of the substrate, which direction may be referred to as the Z-direction. Bowl-shaped and umbrella-shaped substrates are, to a certain degree, flattened out when clamped onto a substrate holder, e.g. by partially evacuating the space between the substrate and substrate holder. However, if the amount of distortion, which is typically measured by the height difference between the lowest point on the surface of the substrate and the highest point on the surface of the substrate, is too great, various problems can arise. In particular, it may be difficult to clamp the substrate adequately, there may be excessive wear of the burls during loading and unloading of substrates and the residual height variation in the surface of the substrate may be too great to enable correct patterning on all parts of the substrate, especially close to the edges.

### SUMMARY

An object of the present invention is to provide a substrate holding system that enables effective pattern formation on a substrate. A substrate holding system according to an embodiment may enable a more consistent substrate loading and clamping process, leading to a reduction in overlay.

In a first embodiment, there is provided a substrate holding system for supporting a substrate, the substrate holding system comprising a substrate holder and an evacuation conduit, wherein the substrate holder comprises: a main body having a surface; a plurality of burls projecting from the surface and having distal ends that form a support surface for the substrate; and an evacuation passage in fluid communication with the evacuation conduit and a space between the surface and the substrate supported by the burls to form an evacuation flow path; and
a proportional valve is provided in the evacuation flow path.

According to the first embodiment, there is also provided a method of clamping a substrate to a substrate to a substrate holder, wherein the substrate holder comprises: a main body having a surface; a plurality of burls projecting from the surface and having distal ends that form a support surface for the substrate; and an evacuation passage in fluid communication with the evacuation conduit and a space between the surface and the substrate supported by the burls to form an evacuation flow path, the method comprising positioning the substrate on the support surface; extracting fluid from a space between the surface and the substrate through the evacuation flow path; and controlling a clamping variable so that the substrate achieves full contact with the support surface in substantially a predetermined time period.

According to a second embodiment, there is provided a device manufacturing method comprising first clamping a substrate having a first radiation sensitive layer to a first substrate holder of a first lithographic apparatus; first exposing the radiation sensitive layer to a first pattern; first processing the substrate to form a first layer based on the first pattern; second clamping the substrate having a second radiation sensitive layer to a second substrate holder of a second lithographic apparatus; second exposing the radiation sensitive layer to a second pattern; and second processing the substrate to form a second layer based on the second pattern; wherein a clamping variable applied during the first clamping and second clamping is determined to minimise overlay between the first layer and the second layer.

According to the present invention, there is also provided a lithographic apparatus comprising the substrate holder.

Further embodiments, features and advantages of the present invention, as well as the structure and operation of the various embodiments features and advantages of the present invention, as well as the structure and operation of the various embodiments of the present invention, are described in detail below with reference to the accompanying drawings.

### BRIEF DESCRIPTION OF THE DRAWINGS

Embodiments of the invention will now be described by way of example only, with reference to the accompanying schematic drawings in which corresponding reference symbols indicate corresponding parts, and in which:

FIG. 1 schematically depicts an overview of a lithographic apparatus;

FIG. 2 depicts a cross section of part of a substrate holder of a first embodiment;

FIG. 3 depicts a plan view of the substrate holder of FIG. 2;

FIG. 4 depicts a substrate holding system according to a first embodiment;

FIG. 5 is a flow diagram of a calibration method in the first embodiment;

FIG. 6 is a flow diagram of a clamping method in the first embodiment;

FIG. 7 depicts a model for determination of flow settings in a second embodiment;

FIG. 8 depicts a variation of the model of FIG. 7;

FIG. 9 depicts another variation of the model of FIG. 7;

FIGS. 10A and 10B depict a proportional valve usable in embodiments of the invention in closed (A) and (B) open condition; and

FIG. 11 schematically depicts a pneumatic system of an embodiment of the invention.

The features shown in the figures are not necessarily to scale, and the size and/or arrangement depicted is not limiting. It will be understood that the figures include optional features which may not be essential to the invention. Furthermore, not all of the features of the substrate holder are depicted in each of the figures, and the figures may only show some of the components relevant for describing a particular feature.

### DETAILED DESCRIPTION

In the present document, the terms “radiation” and “beam” are used to encompass all types of electromagnetic radiation, including ultraviolet radiation (e.g. with a wavelength of 436, 405, 365, 248, 193, 157, 126 or 13.5 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

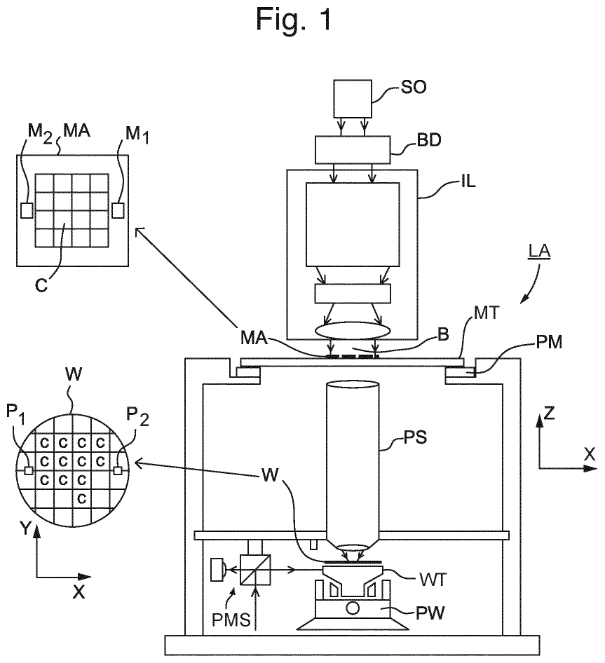

FIG. 1 schematically depicts a lithographic apparatus LA. The lithographic apparatus includes an illumination system (also referred to as illuminator) IL configured to condition a radiation beam B (e.g., EUV radiation or DUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a substrate table or a substrate holder) WT constructed to hold a substrate (e.g., a resist coated wafer) W and connected to a second positioner PW configured to accurately position the substrate support WT in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives the radiation beam B from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus may be of a type wherein at least a portion of the substrate W may be covered by an immersion liquid having a relatively high refractive index, e.g., water, so as to fill an immersion space between the projection system PS and the substrate W—which is also referred to as immersion lithography. More information on immersion techniques is given in U.S. Pat. No. 6,952,253, which is incorporated herein by reference.

The lithographic apparatus may be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus may comprise a measurement stage (not depicted in FIG. 1). The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system PMS, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

In this specification, a Cartesian coordinate system is used. The Cartesian coordinate system has three axis, i.e., an x-axis, a y-axis and a z-axis. Each of the three axes is orthogonal to the other two axes. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

In a lithographic apparatus it is necessary to position with great accuracy the upper surface of a substrate to be exposed in the plane of best focus of the aerial image of the pattern projected by the projection system. To achieve this, the substrate can be held on a substrate holder. The surface of the substrate holder that supports the substrate can be provided with a plurality of burls whose distal ends can be coplanar in a nominal support plane. The burls, though numerous, may be small in cross-sectional area parallel to the support plane so that the total cross-sectional area of their distal ends is a few percent, e.g. less than 5%, of the surface area of the substrate. The gas pressure in the space between the substrate holder and the substrate may be reduced relative to the pressure above the substrate to create a force clamping the substrate to the substrate holder.

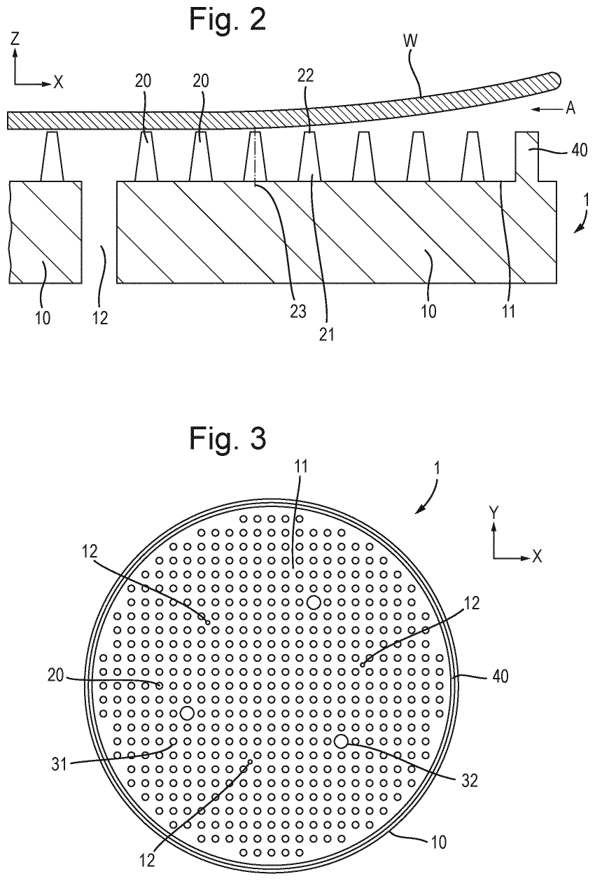

A partial cross section of a substrate holder 1 of a first embodiment is shown in FIG. 2. A plan view of the substrate holder 1 is shown in FIG. 3. The substrate holder 1 comprises a main body 10 having a surface 11. The main body 10 may form a substantial portion of the substrate holder 1. The surface 11 may be a top surface of the main body 10 when positioned as shown in FIG. 2. Thus, the top surface may be an upper surface in the Z-direction as shown.

The substrate holder 1 comprises a plurality of supporting pins 20 connected to the surface 11 of the main body 10. The supporting pins 20 may otherwise be referred to as burls, as described above. The plurality of supporting pins 20 have proximal ends 21, which are situated near the main body 10 when in position, and distal ends 22. The distal ends 22 are at opposite ends of the plurality of supporting pins 20 to the proximal ends 21, i.e. are situated at an end of the supporting pin 20 away from the main body 10.

The plurality of supporting pins 20 have a central longitudinal axis 23, with the proximal end 21 at one end of the supporting pin 20 and the distal end 22 at the other end of the supporting pin 20 along the central longitudinal axis 23. Thus, each of the plurality of supporting pins 20 may have a central longitudinal axis 23 from the proximal end 21 to the distal end 22.

The distal ends 22 of the plurality of supporting pins 20 form a support surface for a substrate W. The distal ends 22 of the plurality of supporting pins 20 may be provided in a plane. Preferably, the support surface is formed in a substantially flat plane, i.e. the distal surfaces of the supporting pins 20 may conform to a flat plane and support the substrate W. This is beneficial as the substrate W can be positioned on the support surface to also be substantially flat, which can reduce errors when patterning the substrate W.

As shown in FIGS. 2 and 3, the plurality of supporting pins 20 may be substantially frusto-conical, i.e. a truncated cone, or may be conical in shape. They may instead be substantially cylindrical. A frustoconical supporting pin 20 may be stronger than a cylindrical pin and thus have less likelihood of breaking. Preferably the plurality of supporting pins 20 have the same shape as each other.

The plurality of supporting pins 20 may be connected to the surface 11 of the main body 10 in any suitable way. The plurality of supporting pins 20 may be separate components which are attached to the surface 11 of the main body 10. Alternatively, the plurality of supporting pins 20 may be integral to the main body 10. In other words, the plurality of supporting pins 20 may be formed as protrusions from the surface 11 of the main body 10, i.e. the plurality of supporting pins 20 may be formed as a single part with the main body 10.

The substrate holder 1 may be configured to enable fluid to be extracted from between the substrate W supported on the support surface and the surface 11. Fluid at the edge of the substrate W may be drawn under the substrate and may be moved in the direction of arrow A as shown in FIG. 2. As fluid is extracted the pressure beneath the substrate W is reduced relative to pressure above the substrate W, and the edge of the substrate W will lower towards the substrate holder 1. The substrate W can be clamped by extracting fluid in the space below the substrate W to provide a reduced relative pressure in the space between the substrate holder 1 and the substrate W.

The main body 10 may comprise at least one extraction opening 12 through which the fluid is extracted. There may be a plurality of extraction openings 12. For example only, there may be three extraction openings 12 as shown in FIG. 3 (although there could be more or less).

It is beneficial to reduce leakage of fluid into the space between the substrate W and the main body 10 when the substrate W is clamped. Therefore, it may be beneficial to provide a physical boundary positioned near the edge of the substrate holder 1. The physical boundary could be formed towards an edge of the main body 10 as shown in FIGS. 2 and 3. The physical boundary could be formed by a sealing member 40. The sealing member 40 may be a wall type protrusion formed around the edge of the main body 10, for example, around the circumference of the main body 10. The sealing member 40 may be formed to provide a seal between the lower side of the substrate W and the substrate holder 1 around the edge of the substrate W. The seal provided by the sealing member 40 need not be a perfect seal but may be a partial seal that reduces but does not eliminate flow of fluid into the space between the substrate holder 1 and substrate W.

The fixed sealing member 40 may surround the plurality of supporting pins 20. The fixed sealing member 40 may protrude from the surface 11 of the main body 10. The fixed sealing member 40 may be connected to the main body 10 in any way. The fixed sealing member 40 may be integral with the main body 10.

A pressure sensor (not depicted in the drawings) may be used to measure the pressure between the substrate W and the surface 11 of the main body 10. Various sensors for measuring the pressure in the space below the substrate W are known. For example, a pressure sensor as disclosed in WO 2017/137129 A1, which is hereby incorporated by reference in its entirety, provides an example of an appropriate pressure sensor which might be used.

A flow rate sensor (not depicted in drawings) may be used to measure the flow rate of the fluid extracted via the extraction opening 12. Various sensors for measuring the flow rate from the space below the substrate W are known.

In the first embodiment, a lithographic apparatus may be provided which comprises a substrate holding system as described above. The lithographic apparatus may have any of the features described above and/or shown in relation to FIG. 1.

In conventional lithographic apparatus, the flow rate of gas extracted from the space below the substrate W is predetermined for a given recipe. A lithographic apparatus may have a few, e.g. 2 or 3, predetermined rates which can be selected between. For example one known lithographic apparatus allows selection between 7.0, 2.7 and 1.3 Nl/min but other rates are possible. For a given recipe, a flow rate is selected to provide a compromise between throughput, average overlay and substrate to substrate overlay variation. A high flow rate provides increased throughput through a faster clamping process and a lower substrate to substrate overlay variation whereas a low flow rate provides a smaller average overlay.

The present inventors have determined that, for a given evacuation flow rate, variations in substrate holders lead to variations in the time taken to complete a clamping process which leads to overlay variations. The clamping process can be considered complete when the bottom of the substrate comes into contact with the outermost ring of burls on the substrate holder and thus achieves full contact with the support surface. The time taken to complete the clamping process is referred to herein as the clamping time. During clamping, especially on bowl-like substrates, pressure gradients across the substrate change over time. This means that local stresses in the substrate W vary over time during the clamping process. This might lead to local variation in virtual slip (hysteresis), depending on friction, and possibly a local inaccuracy in the substrate position. In other words, the speed at which the clamping is carried out affects the clamp behaviour and the possible inaccuracy in substrate position.

The present invention proposes to provide greater flexibility in the selection of the evacuation flow rate, desirably through the provision of a proportional valve in the evacuation flow path, and to calibrate specific substrate holders so that an evacuation flow rate can be set to achieve completion of the clamping process in substantially a predetermined time. This means that where the same recipe is performed on different lithographic apparatus different flow rates may be set in different lithographic apparatus and for a lithographic apparatus having two substrate stages, different flow rates may be set depending on which substrate holder 1 and on which substrate stage a substrate W is being clamped to.

Experiments and simulations suggest that achieving a consistent clamping time leads to more consistent overlay between substrates of a batch, allowing for compensation for the overlay to be performed, e.g. during subsequent exposure steps. It is believed that a consistent clamping process leads to more consistent stress within the clamped substrates and hence more consistent substrate distortions. A consistent duration of the clamping process may also have advantages in scheduling activities in the lithographic apparatus.

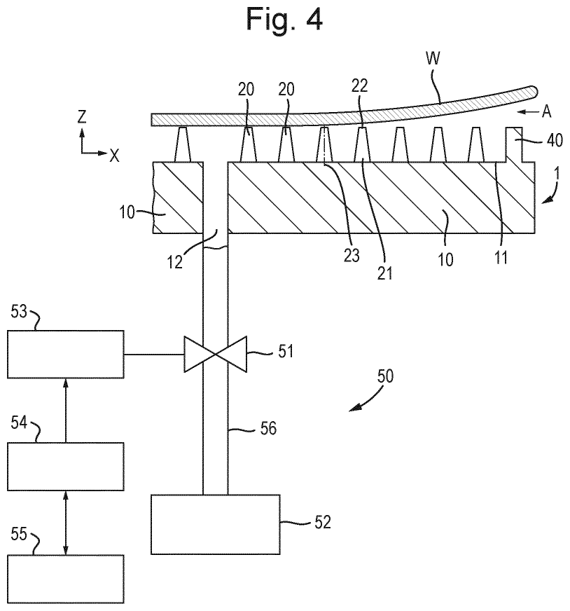

A substrate holding system according to an embodiment of the invention is depicted in FIG. 4. An evacuation system 50 is connected to extraction opening 12 via an extraction passage in order to extract fluid from the space between the substrate W and the substrate holder 1. Evacuation system 50 comprises a vacuum pump 52 connected to the extraction opening 12 by evacuation conduit 56. Evacuation conduit 56 and extraction opening 12 form an evacuation flow path. Other conduits and devices may be included in the evacuation flow path. A proportional valve 51 is provide in the evacuation flow path, for example in the evacuation conduit 56, in order to control the flow resistance of the evacuation flow path and hence the evacuation flow rate when evacuation pump 52 is active.

Various types of valve may be used as proportional valve 51, for example butterfly valves, disc valves and diaphragm valves. Desirably the opening amount of proportional valve 51 is controlled by an actuator 53. Any suitable type of actuator 53 may be used, e.g. a piezo-electric actuator, a solenoid or a stepper motor.

Although only a single evacuation conduit 56 is shown in FIG. 4, multiple parallel branches of evacuation conduit 56 and/or multiple extraction opening 12 may be provided to form the evacuation flow path between evacuation pump 52 and the space between substrate W and substrate holder 1. The different branches of evacuation conduit 56 may be provided with respective proportional valves 51 and may be differently sized to increase the range over which the evacuation flow can be controlled.

Actuator 53 is controlled by controller 54. Controller 54 obtains from calibration data store 55 a set point for the proportional valve(s) 51 in order to achieve a predetermined clamping time using the specific substrate holder 1. A process for obtaining the calibration data is described below. Desirably, the calibration data is obtained from calibration measurements performed on the actual substrate holder 1 being used to clamp a substrate W for device manufacture. In some instances, substrate holders may be grouped into groups having similar characteristics (e.g. type of substrate holder, type of coating, age, amount of use) and calibration data obtained from one or more examplars of the group may be used. The controller 54 may also take into account additional parameters, as well as the calibration data for the specific substrate holder 1 to be used, in order to determine the set point for the proportional valve 51 to achieve the desired predetermined clamping time. Additional parameters may relate to the substrate holder 1, for example the length of time since the calibration data was obtained or the number of uses of the substrate holder 1 since the calibration data was obtained, which may account for wear of the substrate holder 1. Additional parameters may relate to the recipe for the devices being manufactured and/or the specific substrate W to be clamped, e.g. its shape, which can affect clamping time.

The shape of the substrate W may be estimated. The estimated shape of the substrate W may be predicted based on previous measurements taken. For example, measurements may be taken of previously patterned substrates when a particular process or layer is formed. The prediction may be based on the previous measurements, for example, by generating an average shape dependent on these measurement. The shape of the substrate W could be measured using at least one sensor (not depicted in the drawings). Any appropriate sensor and/or system for measuring the shape of the substrate W can be used, such as equipment by MTI Instruments, Inc. for measuring bow and/or warp of a substrate W, e.g. as described on https://www.mtiinstruments.com/applications/wafer-bow-and-warp/. Data relating to the measured shape of the substrate W from the sensor could be provided as feedback to the controller 54.

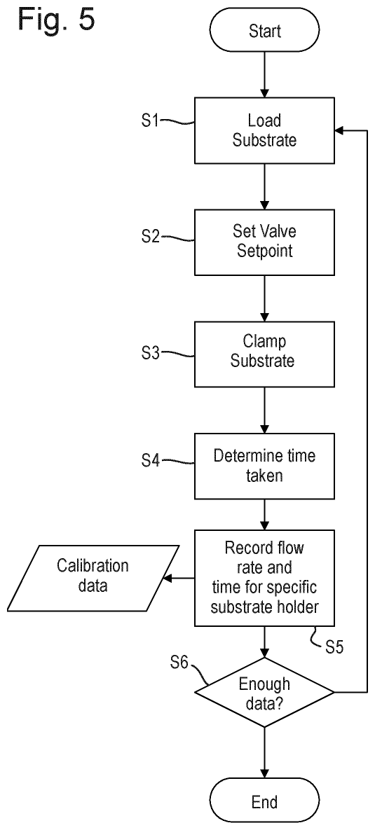

A process for obtaining calibration data of a substrate holder 1 is depicted in FIG. 5. This process may be performed in a lithographic apparatus or in a test rig having the substrate holding system of FIG. 4. A substrate W is loaded S1 into the substrate holder 1 in a conventional manner, e.g. using a gripper robot and e-pins. The proportional valve 51 is set at a set point S2 and the substrate W clamped S3 by evacuating the space between the substrate holder 1 and the substrate W. The time taken for the clamping process to complete is determined S4 (e.g. by determining the time when the outermost burls 20 are contacted by the substrate W). The calibration data, e.g. comprising set point and time taken to complete the clamping process, are stored in association with data identifying the specific substrate holder 1 and/or its relevant characteristics (e.g. type of substrate holder, type of coating, age, amount of use) and optionally data relating to the substrate W used (e.g. degree of warpage and nature of backside coatings). It is then determined S6 whether enough data is available and if not the process is repeated with a different set point and/or a different substrate. The steps of this process do not necessarily need to be performed in the indicated order. For example S2 may be performed before or in parallel with S1 and S6 before or in parallel with S5.

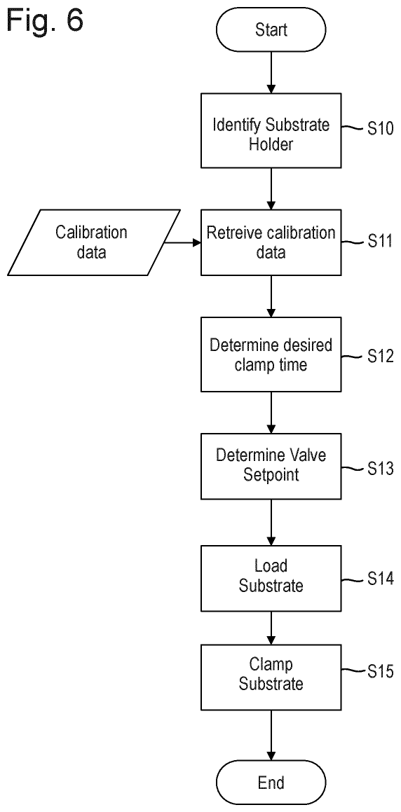

A clamping process according to an embodiment is depicted in FIG. 6. First, the substrate holder 1 to be used and/or its relevant characteristics is identified S10. Based on this information, appropriate calibration data is retrieved S11 from the calibration data store 55. The desired clamping time is determined S12 and, from the calibration data, a valve set point is determined S13 and set to the proportional valve 51. The substrate W is loaded S14 and clamped S15 by evacuating the space between the substrate holder 1 and the substrate W. The steps of this process do not necessarily need to be performed in the indicated order. For example S10 to S13 may be performed after or in parallel with S14.

In the manufacture of some devices having relatively tall features, e.g. DRAM and so-called 3D-NAND, the shape of the substrate W may change significantly between the initial layers and the final layers, e.g. becoming more warped or changing from bowl-shaped to umbrella-shaped. Conventional practice is to select an evacuation flow rate according to the shape of the substrate W to be clamped in order to minimise distortion. Different evacuation flows may give rise to different clamping distortion patterns (which are sometimes referred to as “fingerprints”). Therefore, if the shape of the substrate W changes between patterning two layers, different evacuation flows may be selected for clamping to pattern those two layers.

The present inventors have noted that this approach may not be advantageous in all circumstances. For example, it may be sub-optimal in the case where overlay between a first layer (which is low in the stack but not necessarily the very first layer to be patterned) and a second layer (which is higher in the stack) is important or critical. If the substrate W has changed shape between the patterning of the first layer and the patterning of the second layer, so that different evacuation flows are selected for those patterning steps, the different clamping distortion patterns that arise may increase overlay between the first and second layers.

Accordingly, in a second embodiment it is proposed to select the evacuation flows and/or evacuation pressure for clamping the substrate prior to the patterning of the first layer and prior to the patterning of the second layer together in such a way as to minimise overlay between the first layer and the second layer. The selection of the evacuation flows may take into account the anticipated substrate shape prior to both patterning steps as well as other relevant parameters, such as the substrate holder to be used in each step.

In a lithographic apparatus having a small number of discrete evacuation flows that can be selected between, the second embodiment may select the same evacuation flow rate for clamping prior to both patterning steps, even where that might result in a larger clamping distortion for one or both of the first and second layers.

In the case where a larger number of evacuation flow rates can be chosen between or a continuous control over the evacuation flow rate is possible (e.g. because the proportional valve 51 is provided) the evacuation flow rate for clamping prior to patterning the first layer may be different than evacuation flow rate prior to patterning the second layer, but the two flow rates may be more similar than if they were independently selected.

In the second embodiment, it is desirable to also take into account what corrections are possible by other means, e.g. automated process control in the lithography apparatus. Thus the choice of evacuation flow rate may seek to minimise overlay patterns that cannot be corrected by other means. Alternatively, the choice of evacuation flow rate for clamping may be part of a holistic control strategy taking advantage of all controllable parameters of the patterning process.

Of course there may be multiple pairs of layers in a stack where the overlay is important. Thus the optimisation approach of the second embodiment may be performed multiple times for multiple pairs of layers, which may be in any order or interleaved in the stack. The first layer may be patterned using a first lithographic apparatus and the second layer may be patterned using a second lithographic apparatus. The second lithographic apparatus may be the same lithographic apparatus as the first lithographic apparatus or may be a different lithographic apparatus. Where the same lithographic apparatus is used for both layers, a first substrate holder and a second substrate holder used may be the same or different.

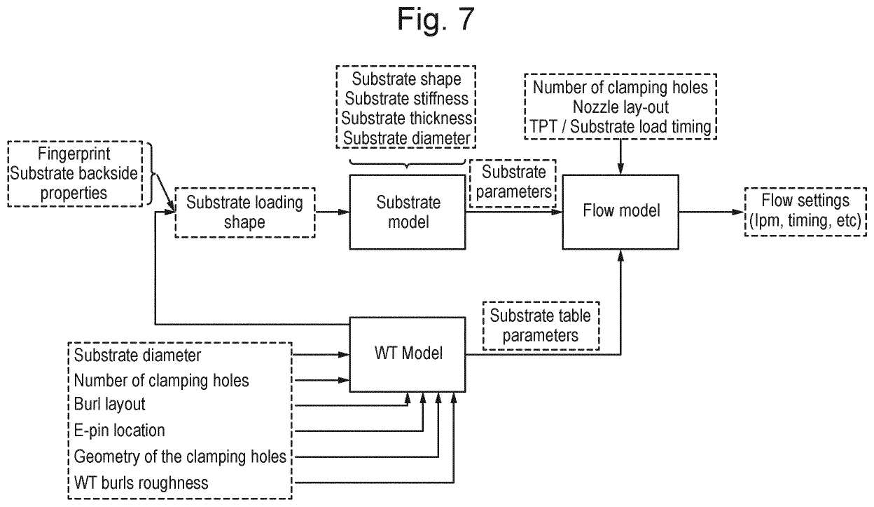

FIG. 7 depicts a system of the second embodiment for determining clamping parameters such as evacuation flow rate for different layers. A substrate model takes as inputs the substrate loading shape, which is associated with a fingerprint (clamping distortion pattern) and other substrate properties such as stiffness, thickness, diameter and backside coating. A substrate holder (WT) model has inputs such: as the substrate W diameter; number of extraction openings 12 (clamping holes); supporting pin (burl) layout, e-pin locations; geometry of clamping holes; and roughness of the supporting pins (burls). The substrate model provides substrate parameters and the substrate holder model provides substrate holder parameters to a flow model. The flow model may have additional inputs such as: the number of clamping holes; layout of extraction openings 12 (nozzles) in the substrate holder 1; throughput (TPT) and substrate load timing. The flow model determines the flow settings, e.g. flow rate and timing, to be applied to clamp the substrate W prior to the patterning of the different layers.

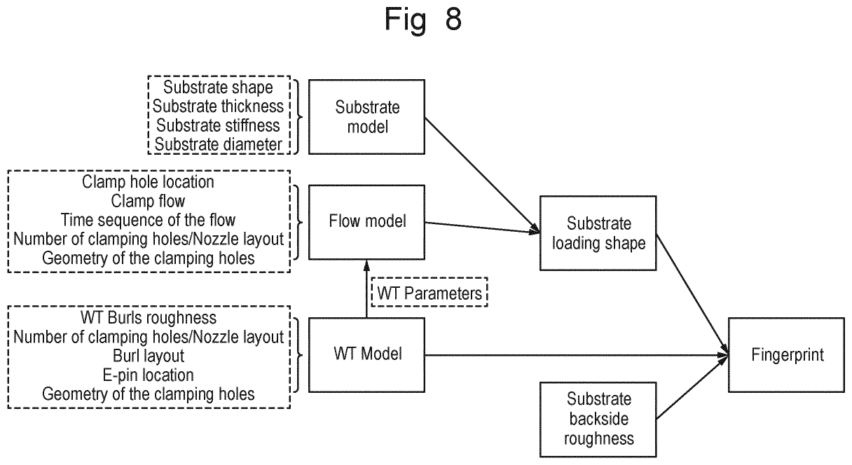

An alternative model of the second embodiment is depicted in FIG. 8. The substrate model takes inputs including: shape, thickness stiffness and diameter; and models the behaviour of the substrate W. The substrate holder (WT) model has inputs including: WT supporting pins (burls) roughness; number of extraction openings 12 (clamping holes) extraction opening layout; burl layout; E-pin location; geometry of the extraction openings 12. The substrate holder model models the behaviour of the substrate holder 1 and output relevant parameters. A flow model takes inputs including the substrate holder parameters and other parameters such as: extraction hole location; clamp flow; time sequence of the flow; number of extraction openings 12; extraction opening layout; geometry of the extraction openings 12. The flow model models the flow of fluid in the clamping procedure and its output, together with the output of the substrate model, is provided to a substrate loading shape model, which predicts the shape adopted by the substrate W when it is loaded onto the substrate holder 1. The substrate loading shape, substrate table model and data relating to the substrate backside roughness are then use to predict the fingerprint (clamping distortion pattern).

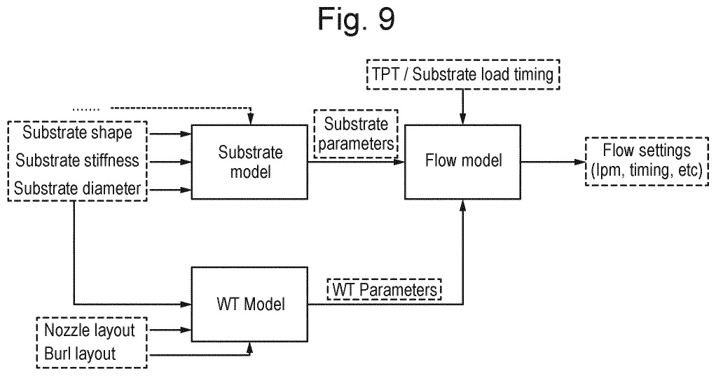

Another, simpler, model of the second embodiment is depicted in FIG. 9. This has a substrate model and a substrate holder model providing inputs to a flow model which outputs the desired flow settings, also referring to throughput and timing information. The substrate model has inputs of relevant substrate parameters such as shape, stiffness and diameter. The substrate holder model has inputs including the substrate diameter, layout of extraction openings 12 and the supporting pin (burl) layout.

It will be appreciated that the first and second embodiments can be combined and flow settings, including flow rate, optimised to provide both a consistent clamping time and a consistent fingerprint between matched layers.

In both the first and second embodiments, rather than a single set point for flow rate during the clamping process, it is possible to set a profile defining changes in flow rate over time.

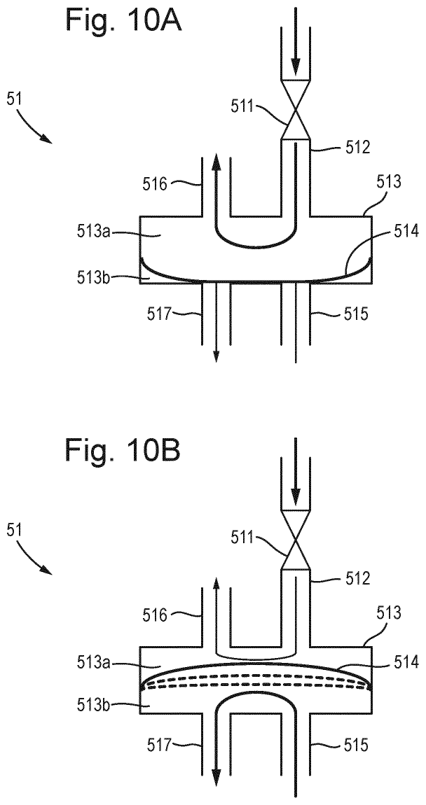

An example of a proportional valve 51 that can be used in embodiments of the present invention is shown in FIGS. 10A and 10B. FIG. 10A shows the proportional valve 51 in a closed configuration and FIG. 10B shows the proportional valve 51 in an open configuration. In proportional valve 51, a proportional piezoelectric valve 511 is used to control a control pressure in an input channel 512 connected to a control chamber 513. The control chamber 513 is divided into two isolated sections 513a, 513b by a flexible membrane 514 which may be impervious. Input conduit 512 is connected to a first section 513a of the control chamber 513 so that the control pressure controls the position of the flexible membrane 514. When the control pressure is high, as depicted in FIG. 10A, flexible membrane 514 is forced to a closed position such that an inlet 515, which is connected to the evacuation system 50, and an outlet 517, which is connected to a vacuum source, such as vacuum pump 52 shown in FIG. 4, are covered. In this configuration, the vacuum source is isolated from the evacuation system 50 and so no clamping vacuum is applied in the substrate holder 1.

If the control pressure is reduced, the flexible membrane 514 moves away from the inlet 515 and outlet 517 so that fluid communication between the vacuum source and the evacuation system 50 is re-established. Control pressure is reduced by partially or completely closing piezoelectric proportional valve 511. Gas within the first section 513a of control chamber 513 can vent e.g. to atmosphere, through outlet 516 so that the pressure in first section 513a of control chamber 513 is reduced. The position of flexible membrane 514 is dependent upon the pressure difference between the first section 513a of the control chamber 513 and the second section 513b, any resilience of the flexible membrane 514 and/or any additional biasing means (not shown) that may be provided. Desirably, the flexible membrane 514 is biased via its own resilience and/or additional biasing means to a position where the vacuum source is in fluid communication with the evacuation system 50 if the pressures in the first section 513a and second section 513b of the control chamber 513 are balanced. The position of the flexible membrane 514 when not completely blocking the inlet 515 and outlet 517 affects the flow resistance between the inlet 515 and outlet 517 so that by varying the control pressure, a variable flow resistance is provided in the evacuation from the evacuation system 50 and a variable clamping pressure can thereby be applied in the evacuation system 50.

The described proportional membrane valve has various advantages. In particular, it can operate reliably whilst incorporated in a substrate table that undergoes high accelerations and may be subject to varying and strong magnetic fields. The flexible membrane 514 can be chosen to be impervious to liquid, e.g., water so that if any immersion liquid is extracted, no damage occurs. High flow rates, e.g. greater than 50 lpm, can readily be accommodated.

Pressure sensors (not shown) may be provided, for example in the first and second sections 513a, 513b of the control chamber 515 in order to monitor correct operation of the proportional valve 51.

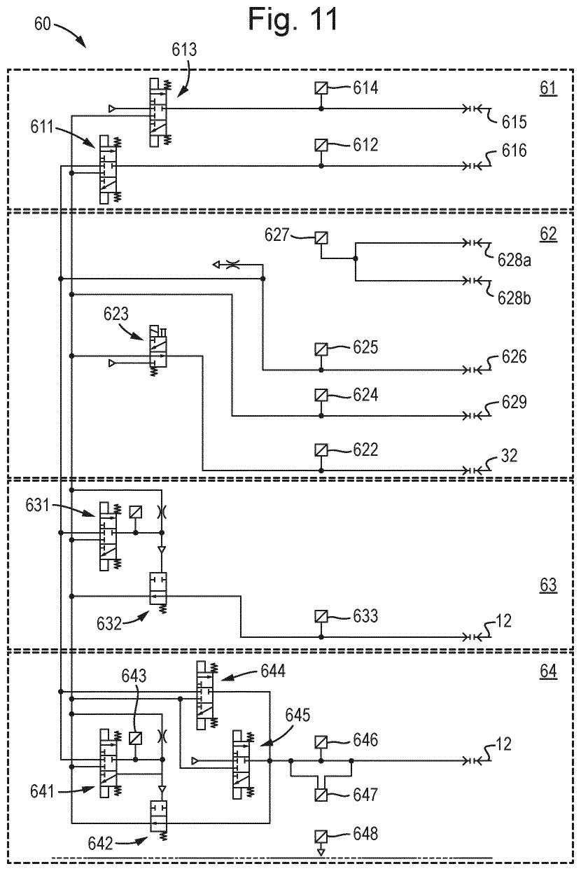

A simplified schematic of a pneumatic system for controlling clamping of substrates is depicted in FIG. 11. The pneumatic system comprises several different channels, supplying or extracting fluids to or from different parts of the substrate holder 1.

A first channel 61 provides clean dry air during substrate load and a connection to ambient 615 where required. Piezo valve 611 controls a supply of extreme clean dry air (XCDA) to outlet 616 near the edge of the substrate W to control the edge of substrate W during loading and unloading operations, known as edge lift. Piezo valve 613 controls the connection to ambient 615. These valves may be replaced by proportional membrane valves as discussed above to provide additional control over the edge lift and ambient flows as described in EP22179329.2, which document is incorporated herein by reference. Pressure sensors 612, 614 are provided to measure the pressure in the ambient and extraction channels in order to confirm proper operation

A second channel 62 provides extraction in the vicinity of the e-pins 32 under control of solenoid valve 623, with pressure sensor 622 for monitoring. Extraction of fluid, e.g. a mixture of liquid and gas, from the vicinity of the edge of the substrate W is provided by outlet 628a which is permanently connected to extraction vacuum 628b, with pressure sensor 627 for monitoring. There is also a connection 626 to a clean dry air supply (e.g. XCDA) monitored by pressure sensor 625 and a common wet vacuum connection 629 monitored by pressure sensor 624.

A third channel 63 provides the clamping vacuum to extraction openings 12 under proportional control provided by piezo valve 631 and membrane valve 632. Pressure sensor 633 provides monitoring.

A fourth channel 64 provides proportional controlled extraction during the loading and unloading process, often referred to as “pre-clamp”. Proportional control is provided by piezo valve 641 and membrane valve 642 whilst two piezo valves 644 and 645 provide for pre-set extraction rates. Pressure sensors 643, 646 and 647 provide monitoring. Fourth channel 64 is shown as connected to the extraction openings 12 but may also or in the alternative be connected to other dedicated openings in the substrate holder 1 (not shown).

It will also be appreciated that the principles of the present invention can be applied to lithographic tools and clamping systems that employ electrostatic clamps. In such a case, rather than controlling the flow rate of an evacuation flow, other relevant parameters such as the voltage applied to the electrostatic clamp may be controlled.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains one or multiple processed layers.

Although specific reference may have been made above to the use of embodiments of the invention in the context of optical lithography, it will be appreciated that the invention may be used in other applications.

While specific embodiments of the invention have been described above, it will be appreciated that the invention may be practiced otherwise than as described.

The descriptions above are intended to be illustrative, not limiting. Thus, it will be apparent to one skilled in the art that modifications may be made to the invention as described without departing from the scope of the claims set out below.

1. A substrate holding system for supporting a substrate, the substrate holding system comprising:
a substrate holder;
an evacuation conduit, wherein the substrate holder comprises: a main body having a surface, a plurality of burls projecting from the surface and having distal ends that form a support surface for the substrate, and an extraction passage in fluid communication with the evacuation conduit and a space between the surface and the substrate supported by the burls to form an evacuation flow path; and
a proportional valve in the evacuation flow path.

2. The substrate holding system of claim 1, wherein the evacuation flow path has a first branch and a second branch in parallel with the first branch and the proportional valve is provided in the first branch.

3. The substrate holding system of claim 2, further comprising an additional proportional valve in the second branch.

4. The substrate holding system of claim 2, wherein one of the first and second branches is configured to allow a greater flow rate therethrough than the other of the first and second branches.

5. (canceled)

6. The substrate holding system of claim 1, wherein the proportional valve comprises a membrane valve.

7. A lithographic apparatus comprising the substrate holding system of claim 1.

8. A method of clamping a substrate to a substrate holder, wherein the substrate holder comprises: a main body having a surface; a plurality of burls projecting from the surface and having distal ends that form a support surface for the substrate; and an extraction passage in fluid communication with a space between the surface and the substrate supported by the burls to form an evacuation flow path, the method comprising:
positioning the substrate on the support surface;
extracting fluid from the space between the surface and the substrate through the evacuation flow path; and
controlling a clamping variable so that the substrate achieves full contact with the support surface in substantially a predetermined time period.

9. The method of claim 8, wherein the clamping variable is a flow resistance of the evacuation flow path.

10. The method of claim 8, wherein the controlling comprises looking up a control set point in a set point storage device storing one or more set points.

11. A non-transitory computer program product having stored instructions, the instructions, when executed by an apparatus, configured to cause the apparatus to at least:
obtain a set point associated with a substrate holder of a substrate holding system, the substrate holding system comprising an evacuation flow path for extracting fluid from a space between the substrate holder and a substrate to provide clamping of the substrate, the evacuation flow path having a proportional valve; and
control the proportional valve based on the set point.

12. A device manufacturing method comprising:
first clamping a substrate having a first radiation sensitive layer to a first substrate holder of a first lithographic apparatus;
first exposing the radiation sensitive layer to a first pattern;
first processing the substrate to form a first layer based on the first pattern;
second clamping the substrate having a second radiation sensitive layer to a second substrate holder of a second lithographic apparatus;
second exposing the second radiation sensitive layer to a second pattern; and
second processing the substrate to form a second layer based on the second pattern,
wherein a clamping variable applied during the first clamping and second clamping is determined to minimise overlay between the first layer and the second layer.

13. The method of claim 12, wherein the clamping variable is an evacuation flow rate, an evacuation pressure, a timing of the clamping process or a clamping voltage, and/or wherein the clamping variable is the same during the first clamping and the second clamping.

14. The method of claim 12, wherein the clamping variable is determined based on the value of a parameter of the substrate prior to the first clamping and the value of the parameter of the substrate prior to the second clamping, and/or wherein the clamping variable is determined so that substrate distortion caused during the first clamping is similar to substrate distortion caused during the second clamping.

15. The method of claim 12, wherein the first lithographic apparatus and the second lithographic apparatus are the same lithographic apparatus, and/or wherein the first substrate holder and the second substrate holder are the same substrate holder.

16. The substrate holding system of claim 1, further comprising an actuator connected to the proportional valve and configured to control the amount of opening of the proportional valve.

17. The substrate holding system of claim 16, further comprising a controller configured to control the actuator during a substrate clamping process so that the time taken for the substrate clamping process is substantially equal to a predetermined time period.

18. The substrate holding system of claim 17, wherein the controller comprises a set point storage device storing one or more set points for the actuator.

19. The computer program product of claim 11, wherein the evacuation flow path has a first branch and a second branch in parallel with the first branch and the proportional valve is provided in the first branch.

20. The computer program product of claim 11, wherein the proportional valve comprises a membrane valve.

21. The computer program product of claim 11, wherein the instructions configured to control the proportional valve are further configured to cause the apparatus to control an actuator connected to the proportional valve to control the amount of opening of the proportional valve.
